(19) United States
(12) Patent Application Publication
(10) Pub. No.: US 2025/0185375 A1
(43) Pub. Date: Jun. 5, 2025

(54) Semiconductor Die Having a Resistive and/or Diodic Connection between Terminals of a Current sense device and a Power Transistor

(71) Applicant: Infineon Technologies Austria AG, Villach (AT)

(72) Inventors: Matteo Dainese, München (DE); Tillmann Walther, Dresden (DE); Aleksander Hinz, Dresden (DE); Thomas Hunger, Dresden (DE); Matthias Fiebig, München (DE)

(21) Appl. No.: 18/524,125

(22) Filed: Nov. 30, 2023

(51) Int. Cl. H01L 27/02; H01L 29/866

(52) U.S. Cl. CPC H10D 89/611; H10D 8/25

(57) ABSTRACT

A semiconductor die includes: a semiconductor substrate; a power transistor formed in the semiconductor substrate; a current sense device formed in the semiconductor substrate and occupying less area of the semiconductor substrate than the power transistor; a first contact pad electrically connected to a first load terminal of the power transistor; a second contact pad electrically connected to a sense terminal of the current sense device, the second contact pad being dedicated to current sensing only; and a resistive and/or diodic connection between the sense terminal of the current sense device and the first load terminal of the power transistor. The resistive and/or diodic connection is designed solely for ESD (electrostatic discharge) protection of the current sense device, by providing an ESD discharge path to the first load terminal of the power transistor.

### BACKGROUND

For semiconductor devices, an ESD (electrostatic discharge) ruggedness test is a ‘charge injection’ stress test whereby a certain amount of electric charge is forced into an electrical access point to the device. The level of the charge injection is increased until irreversible damage is measured, either as drift of electrical outputs or as a catastrophic failure of dielectric isolation within the device (e.g., gate oxide, interlayer dielectric, etc.). ESD ruggedness is one of the defining SOA (safe operating area) specifications of a semiconductor device.

In power transistor chips (dies), typical ruggedness verification is executed according to the HBM (human body model) ESD specification, whereby a capacitor of 100 pF, charged up to a certain voltage, is discharged over an electrical contact of the chip, through a 1.5 kOhm resistor. The remaining electrical contacts are alternatively grounded, during each separate test, or left floating. Typical SOA specifications require at least 2 kV at the capacitor without electrical damage to the device, in every possible stress combination.

The ESD protection of a power transistor before assembly on a PCB is achieved only with monolithically integrated solutions. IGBT (insulated-gate bipolar transistor) chips, used, e.g., in main inverter applications in electric vehicles, are typically large chips and the gate, emitter, and collector terminals therefore easily meet the ESD specifications, through their associated capacitance. However, for more advanced inverter systems, IGBT chips with an integrated current sensor are used. The current sensor is typically implemented as a small IGBT integrated in the larger main chip and the area ratio can reach up to 1:10,000. The small size of the current sensor area (e.g., down to 0.01 mm²) makes the current sensor area potentially weak in terms of ESD ruggedness and often the HBM specifications for the current sensor area need to be relaxed to below 2 kV. However, not all applications can tolerate this ESD ruggedness de-rating.

Thus, there is a need for a solution that improves ESD ruggedness of integrated current sensors in power transistor chips (dies) such as IGBTs.

### SUMMARY

According to an embodiment of a semiconductor die, the semiconductor die comprises: a semiconductor substrate; a power transistor formed in the semiconductor substrate; a current sense device formed in the semiconductor substrate and occupying less area of the semiconductor substrate than the power transistor; a first contact pad electrically connected to a first load terminal of the power transistor; a second contact pad electrically connected to a sense terminal of the current sense device, wherein the second contact pad is dedicated to current sensing only; and a resistive and/or diodic connection between the sense terminal of the current sense device and the first load terminal of the power transistor, wherein the resistive and/or diodic connection is designed solely for ESD (electrostatic discharge) protection of the current sense device, by providing an ESD discharge path to the first load terminal of the power transistor.

According to another embodiment of a semiconductor die, the semiconductor die comprises: a semiconductor substrate; an IGBT (insulated gate bipolar transistor) formed in the semiconductor substrate; a current sense device formed in the semiconductor substrate and occupying less area of the semiconductor substrate than the IGBT; an emitter contact pad electrically connected to an emitter terminal of the IGBT; a current sense contact pad electrically connected to an emitter terminal of the current sense device, wherein the current sense contact pad is dedicated to current sensing only; and a resistive and/or diodic connection between the emitter terminal of the current sense device and the emitter terminal of the IGBT, wherein the resistive and/or diodic connection is designed solely for ESD protection of the current sense device, by providing an ESD discharge path to the emitter terminal of the IGBT.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a schematic diagram of a semiconductor die has having a resistive and/or diodic connection between a sense terminal of a current sense device and a load terminal of a power transistor, according to an embodiment.

FIG. 2 illustrates a schematic diagram of the semiconductor die, according to another embodiment.

FIG. 3 illustrates a schematic diagram of the semiconductor die, according to another embodiment.

FIG. 4 illustrates a schematic diagram of the resistive and/or diodic connection, according to another embodiment.

FIG. 5 illustrates a schematic diagram of the resistive and/or diodic connection, according to another embodiment.

FIG. 6 illustrates a schematic diagram of the resistive and/or diodic connection, according to another embodiment.

FIG. 7 illustrates a schematic diagram of an overcurrent detection circuit for detecting when current mirrored by the current sense device included in the semiconductor die exceeds a threshold limit.

FIG. 8 illustrates a top plan view of the semiconductor die in a region where the current sense device borders the power transistor.

FIG. 9 illustrates a cross-sectional view of a trench structure in the region where the current sense device borders the power transistor, along the line labelled A-A′ in FIG. 8.

FIG. 10 illustrates a top plan view of the semiconductor die in a region where the current sense device borders the power transistor, according to another embodiment.

FIG. 11 illustrates a top plan view of the semiconductor die in a region where the current sense device borders the power transistor, according to another embodiment.

FIG. 12A illustrates a schematic diagram of the semiconductor die and FIG. 12B illustrates a corresponding top plan view of the semiconductor die in a region where the current sense device borders the power transistor, according to another embodiment.

FIG. 13A illustrates a schematic diagram of the semiconductor die and FIG. 13B illustrates a corresponding top plan view of the semiconductor die in a region where the current sense device borders the power transistor, according to another embodiment.

FIG. 14A illustrates a schematic diagram of the semiconductor die and FIG. 14B illustrates a corresponding top plan view of the semiconductor die in a region where the current sense device borders the power transistor, according to another embodiment.

FIG. 15 illustrates a schematic diagram of a Zener-configured diode shown in FIGS. 14B, according to another embodiment.

### DETAILED DESCRIPTION

Described herein is an improved ESD (electrostatic discharge) protection scheme for an integrated current sense device included in a power transistor die (chip) such as an IGBT die. The current sense device occupies less area than the power transistor integrated in the same die, and thus has less charge storage capacity in the event of an ESD occurrence at a sense terminal of the current sense device. The ESD protection schemes described herein improve ESD ruggedness of the current sense device, by providing a resistive and/or diodic connection between the sense terminal of the current sense device and a load terminal of the power transistor. The resistive and/or diodic connection is designed solely for ESD protection of the current sense device.

During an ESD event, a short circuit event, or during turn-on, high frequency oscillations can occur between the current sense device and, e.g., the main emitter part of an IGBT. The resistive and/or diodic connection acts as a short at the high frequency, effectively shunting the oscillations to the main emitter part of the IGBT. The main emitter part of the IGBT has a significantly larger capacitance and thus greater charge storage capacity compared to the current sense device, and therefore is more robust at absorbing high frequency oscillations without ESD failure and/or gate oxide breakdown/gate oxide reliability issues. The ESD protection schemes are described herein in the context of IGBT power transistors but are equally applicable to other power transistor types such as power MOSFETs (metal-oxide-semiconductor field-effect transistors), JFETs (junction-gate field-effect transistors), etc.

Described next, with reference to the figures, are exemplary embodiments of the ESD protection schemes.

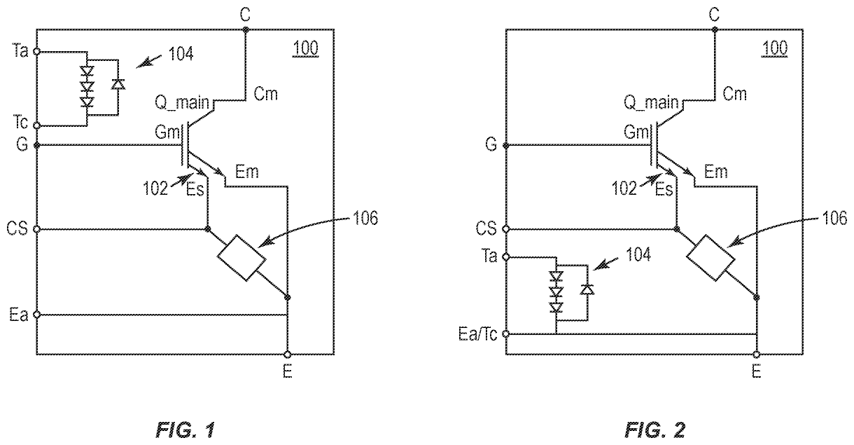

FIG. 1 illustrates a schematic diagram of a semiconductor die 100, according to an embodiment. The semiconductor die 100 includes a power transistor Q_main formed in a semiconductor substrate. The semiconductor substrate is not shown in FIG. 1 since FIG. 1 is a schematic representation of the semiconductor die 100. The semiconductor substrate may comprise one or more semiconductor materials that are used to form semiconductor devices such as power MOSFETs, IGBTs, JFETs, etc. For example, the semiconductor substrate may include Si, silicon carbide (SiC), germanium (Ge), silicon germanium (SiGe), gallium nitride (GaN), gallium arsenide (GaAs), and the like. The semiconductor substrate may be a bulk semiconductor material or may include one or more epitaxial layers grown on a bulk semiconductor material.

A current sense device 102 is formed in the semiconductor substrate and occupies less area of the semiconductor substrate than the power transistor Q_main. The current sense device 102 is schematically illustrated in FIG. 1 as an auxiliary part of the power transistor Q_main. In physical form, the current sense device 102 may have the same transistor cell construction as the power transistor Q_main but the current sense cells occupy less area of the semiconductor substrate than the power transistor cells. For example, the area ratio of the current sense device 102 to the power transistor Q_main may be about 1:10,000. This is just an example, however, and a higher or lower area ratio is possible.

In each case, the semiconductor die 100 includes a first load terminal contact pad ‘E’ electrically connected to a first load terminal ‘Em’ of the power transistor Q_main and a second (current sense) contact pad ‘CS’ electrically connected to a sense terminal ‘Es’ of the current sense device 102. In the case of an IGBT transistor, the first load terminal Em of the power transistor Q_main is an emitter terminal and the sense terminal Es of the current sense device 102 is an emitter terminal. For a MOSFET, the first load terminal Em of the power transistor Q_main is a source terminal and the sense terminal Es of the current sense device 102 is a source terminal.

The term ‘contact pad’ as used herein refers to an exposed metallized region of the semiconductor die 100 that is configured for external contacting, e.g., by a probe of a test system or by an external electrical contact such as one or more bond wire(s), metallic ribbon(s), metallic clip(s), solder ball(s), Cu stud(s), etc. In other words, the contact pads of the semiconductor die 100 provide points of external electrical contact for devices integrated in the semiconductor die 100 such as the power transistor Q_main and the current sense device 102.

The current sense contact pad CS electrically connected to the sense terminal Es of the current sense device 102 is dedicated to current sensing only. That is, temperature sensing, if available at the semiconductor die 100, is implemented through a different contact pad than the current sense contact pad CS electrically connected to the sense terminal Es of the current sense device 102. Accordingly, the current sense contact pad CS is not a shared contact pad.

For example, as shown in FIG. 1, a temperature sense device 104 such as antiparallel connected diodes may be integrated in the semiconductor die 100 together with the power transistor Q_main and the current sense device 102. In FIG. 1, two additional (temperature sense) contact pads ‘Ta’, ‘Tc’ are electrically connected to respective terminals of the temperature sense device 104. The current sense device 102 is electrically and physically isolated from the temperature sense device 104, and the temperature sense contact pads Ta, Tc electrically connected to the terminals of the temperature sense device 104 are dedicated to temperature sensing only.

Whether or not the semiconductor die 100 includes an integrated temperature sense device 104, the semiconductor die 100 has a resistive and/or diodic connection 106 between the sense terminal Es of the current sense device 102 and the first load terminal Em of the power transistor Q_main, where ‘diodic’ means of, pertaining to, or functioning as a diode and ‘resistive’ means of, tending toward, or marked by resistance. The resistive and/or diodic connection 106 can be a purely resistive connection, a purely diodic connection, or both a resistive connection and a diodic connection.

The resistive and/or diodic connection 106 is designed solely for ESD (electrostatic discharge) protection of the current sense device 102, by providing an ESD discharge path to the first load terminal Em of the power transistor Q_main which may be connected to AC ground. The ESD discharge path enabled by the resistive and/or diodic connection 106 is a controlled connection, which is enabled during an ESD event at the sense terminal Es of the current sense device 102.

As explained above, the current sense device 102 occupies less area of the semiconductor substrate than the power transistor Q_main. Accordingly, the current sense device 102 has relatively low charge storage capacity compared to the power transistor Q_main in the event of an ESD occurrence. The resistive and/or diodic connection 106 protects the current sense device 102, by providing an ESD discharge path to the first load terminal Em of the power transistor Q_main.

In the case of an IGBT device for both the current sense device 102 and the power transistor Q_main, the main emitter part of the power transistor Q_main has a significantly larger capacitance and thus grater charge storage capacity compared to the emitter part of the current sense device 102. By providing an ESD discharge path from the sense terminal Es of the current sense device 102 to the emitter terminal Em of the power transistor Q_main via the resistive and/or diodic connection 106, ESD events are safely discharged into the main emitter part of the power transistor Q_main.

The semiconductor die 100 has additional contact pads such as an auxiliary contact pad ‘Ea’ electrically connected to the first load terminal Em of the power transistor Q_main, e.g., to enable Kelvin sensing, a contact pad ‘C’ that is electrically connected to a second load terminal Cm of the power transistor Q_main, and a contact pad ‘G’ that is electrically connected to a gate terminal Gm of both the power transistor Q_main and the current sense device 102. In the case of an IGBT transistor, the second load terminal Cm of the power transistor Q_main is a collector terminal. For a MOSFET, the second load terminal Cm of the power transistor Q_main is a drain terminal. As indicated in FIG. 1, the power transistor Q_main and the current sense device 102 may share the gate connection and the second load terminal connection.

FIG. 2 illustrates a schematic diagram of the semiconductor die 100, according to another embodiment. In FIG. 2, the temperature sense device 104 and the auxiliary load terminal for the power transistor Q_main share a contact pad ‘Ea/Tc’. Doing so reduces the contact pad count for the semiconductor die 100 by one. However, the current sense contact pad CS electrically connected to the sense terminal Es of the current sense device 102 remains dedicated to current sensing only. Temperature sensing is still implemented through different contact pads Ta, Ea/Tc than the current sense contact pad CS electrically connected to the sense terminal Es of the current sense device 102, ensuring the current sense contact pad CS is not a shared contact pad.

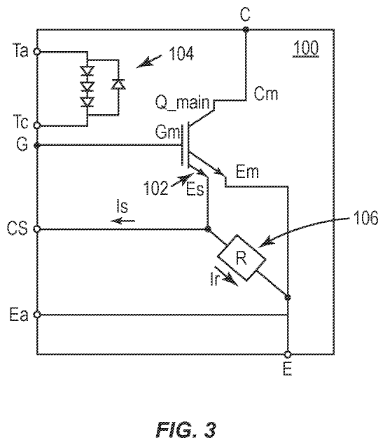

FIG. 3 illustrates a schematic diagram of the semiconductor die 100, according to another embodiment. In FIG. 3, the resistive and/or diodic connection 106 is implemented as a resistive (linear ohmic) connection having a resistance value ‘R’ such that current leakage Ir between the sense terminal Es of the current sense device 102 and the first load terminal Em of the power transistor Q_main is at least ten times smaller than a current Is sensed by the current sense device 102 in an on-state of the power transistor Q_main.

By selecting the resistance value R such that Is/Ir>10, an ESD discharge path is activated under ESD stress conditions and couples the sense terminal Es of the current sense device 102 to the first load terminal Em of the power transistor Q_main to provide an additional charge storage reservoir, dispersing the ESD charge injection and thus boosting the ESD ruggedness of the current sense device 102 at the current sense contact pad CS. In the off-state of the power transistor Q_main, both the current sense contact pad CS and the first load terminal contact pad E are grounded and therefore there is no leakage between the sense terminal Es of the current sense device 102 and the first load terminal Em of the power transistor Q_main.

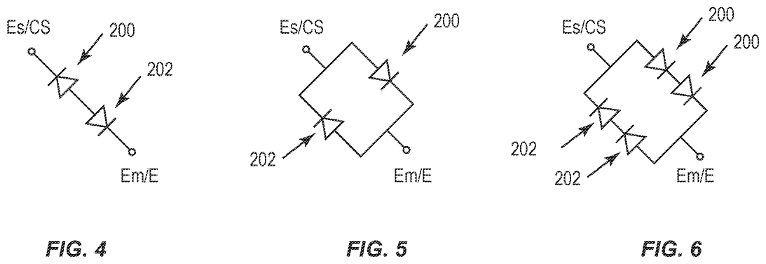

FIG. 4 illustrates a schematic diagram of the resistive and/or diodic connection 106, according to another embodiment. In FIG. 4, the resistive and/or diodic connection 106 is implemented as a diodic (non-linear ohmic) connection that electrically isolates the sense terminal Es of the current sense device 102 and the first load terminal Em of the power transistor Q_main for voltage differences between the terminals Es, Em that are below a threshold value and electrically shorts the terminals Es, Em for voltage differences between the terminals Es, Em that are above the threshold value. If the diodic connection is implemented using polysilicon diodes, for 1 diode, the threshold value is: 0.7V at room temperature and between 0.3 to 0.4V at 200 degrees Celsius for Si.

In FIG. 4, the diodic connection includes a pair of diodes 200, 202 such as TVS (transient-voltage-suppression) diodes coupled anode-to-anode between the sense terminal Es of the current sense device 102 and the first load terminal Em of the power transistor Q_main to approximate a Zener diode, where the breakdown region defines the protection. The TVS diodes 200, 202 instead may be coupled in a cathode-to-cathode configuration.

In either case, the TVS diodes 200, 202 provide isolation (‘blocking effect’) between the current sense contact pad CS and the first load terminal contact pad E of the semiconductor die 100 for small voltage differences but shorts (‘shorting effect’) the current sense contact pad CS to the first load terminal contact pad E for high voltage pulses, such as the ones expected from ESD stress. When the potential at the current sense contact pad CS of the semiconductor die 100 is high (positive or negative) enough relative to the first load contact pad E, one of the TVS diodes 200, 202 enters breakdown at a certain voltage. The diodic connection becomes a short when the voltage pulse applied to the current sense contact pad CS exceeds this breakdown voltage plus the pn junction voltage of the other TVS diode 202, 200, dispersing the ESD charge injection and thus boosting the ESD ruggedness of the current sense device 102 at the current sense contact pad CS. The threshold which separates the ‘blocking effect’ from the ‘shorting effect’ between the sense terminal Es of the current sense device 102 and the first load terminal Em of the power transistor Q_main is defined by the breakdown voltage of the diodes 200, 202, since the diodes 200, 202 face each other in the embodiment illustrated in FIG. 4. More than two TVS diodes 200, 202 may be used to form the diodic connection.

FIG. 5 illustrates a schematic diagram of the resistive and/or diodic connection 106, according to another embodiment. In FIG. 5, the resistive and/or diodic connection 106 is implemented as a diodic connection formed by a single first diode 200 electrically connected back-to-back (anode-to-anode in FIG. 5) with a single second diode 202 between the sense terminal Es of the current sense device 102 and the first load terminal Em of the power transistor Q_main.

FIG. 6 illustrates a schematic diagram of the resistive and/or diodic connection 106, according to another embodiment. In FIG. 6, the resistive and/or diodic connection 106 is implemented as a diodic connection formed by two or more first diodes 200 electrically connected antiparallel to two or more second diodes 202 between the sense terminal Es of the current sense device 102 and the first load terminal Em of the power transistor Q_main. In FIGS. 5 and 6, the threshold which separates the ‘blocking effect’ from the ‘shorting effect’ between the sense terminal Es of the current sense device 102 and the first load terminal Em of the power transistor Q_main is defined by the pn junction forward voltage of the diodes 200, 202. In yet another embodiment, the resistive and/or diodic connection 106 may be implemented using a single diode 200 and two or more antiparallel diodes 202 or as two or more series-connected diodes 200 and a single antiparallel diode 202.

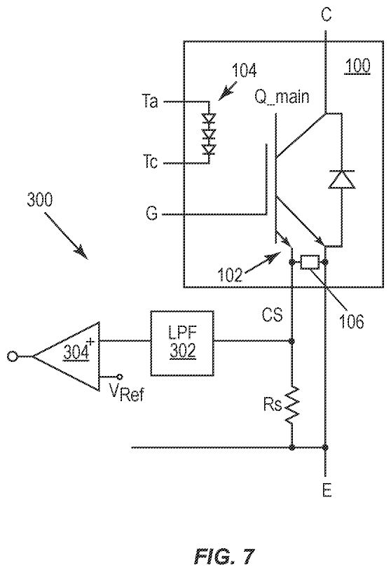

FIG. 7 illustrates a schematic diagram of an overcurrent detection circuit 300 for detecting when the current mirrored by the current sense device 102 included in the semiconductor die 100 exceeds a threshold limit. The overcurrent detection circuit 300 includes a sense resistor Rs, the voltage across which corresponds to the current sensed by the current sense device 102 included in the semiconductor die 100. The overcurrent detection circuit 300 also includes a low pass filter (LPF) 302 and a comparator 304 which has as inputs a reference voltage Vref and the output of the LPF 302. The output of the comparator 304 is enabled or active when the output of the LPF 302 exceeds the reference voltage Vref, indicating an overcurrent condition.

In normal operation, the voltage drop across sense resistor Rs of the overcurrent detection circuit 300 is typically less than 1V such that no more than 1V difference arises between the current sense contact pad CS and the first load terminal contact pad E of the semiconductor die 100 during normal operation. Since the pn junction forward voltage decreases with temperature, enough pn junctions may be used to safely guarantee at least 1V (e.g., up to 1.5V) isolation from, e.g., −40° C. to 185° C. For a TVS diode, a suitable value of the breakdown voltage may be designed such that a single TVS diode is enough to cover the voltage range across the full temperature range of interest.

Accordingly, up to 1.5V isolation for the diodic connection embodiments shown in FIGS. 4 through 6 should be sufficient to ensure that the isolation between the current sense contact pad CS and the first load terminal contact pad E of the semiconductor die 100 is useful only within the input dynamic range (e.g., 500 mV to 1V) of the comparator 304. Even 1V isolation should be sufficient. The diodic connection becomes a short outside the input dynamic range of the comparator 304, dispersing the ESD charge injection and thus boosting the ESD ruggedness of the current sense device 102 at the current sense contact pad CS.

Described next are exemplary implementation examples for the resistive and/or diodic connection 106 included in the semiconductor die 100. In some examples, the resistive and/or diodic connection 106 is a purely resistive connection. In other examples, the resistive and/or diodic connection 106 is a purely diodic connection. In still other examples, the resistive and/or diodic connection 106 is both a resistive connection and a diodic connection. The examples for the resistive and/or diodic connection 106 described below are explained in the context of IGBT power transistors but are equally applicable to other power transistor types such as power MOSFETs, JFETs, etc.

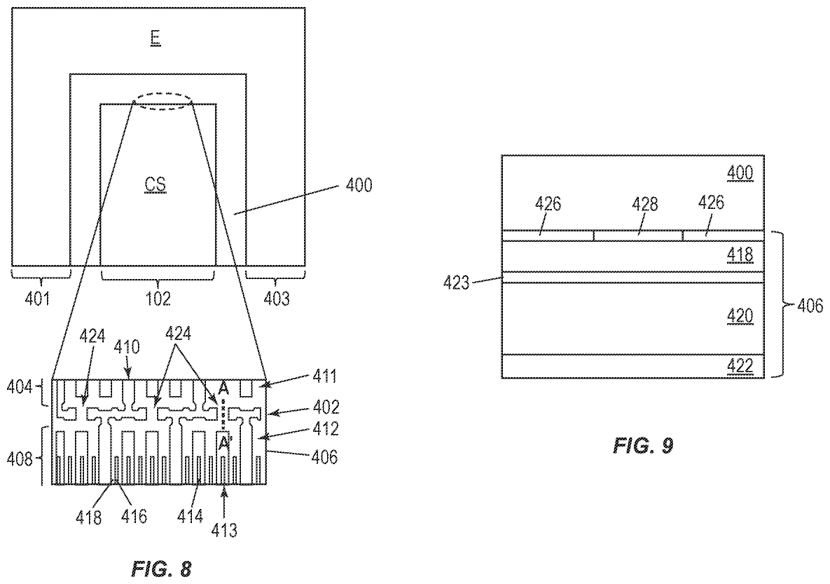

FIG. 8 illustrates a top plan view of the semiconductor die 100 in a region where the current sense device 102 borders the power transistor Q_main. The current sense contact pad CS and the first load terminal contact pad E of the semiconductor die 100 are visible in FIG. 8 since the contact pads CS, E are exposed metallized regions that are configured for external contacting. An insulation layer 400 such as an interlayer dielectric or a field oxide also is shown in FIG. 8, in a gap between the contact pads CS, E. The lower part of FIG. 8 includes an enlarged plan view of the semiconductor die 100, below the contact pads CS, E and the insulation layer 400. In one embodiment, the current sense device 102 is laterally interposed between a first part 401 of the power transistor Q_main and a second part 403 of the power transistor Q_main such that the current sense device 102 borders the first part 401 of the power transistor Q_main on a first side of the current sense device 102 and borders the second part 403 of the power transistor Q_main on a second side of the current sense device 102 different than the first side. In FIG. 8, the current sense device 102 borders the power transistor Q_main on three different sides of the current sense device 102.

Also, in FIG. 8, a trench structure 402 laterally separates a first region 404 of the semiconductor substrate 406 that includes the power transistor Q_main from a second region 408 of the semiconductor substrate 406 that includes the current sense device 102. FIG. 9 illustrates a cross-sectional view along the line labelled A-A′ in FIG. 8.

The trench structure 402 may laterally surround the second region 408 of the semiconductor substrate 406 on one or more side. Gate trenches 410 that form part of the transistor cells of the power transistor Q_main may laterally branch out from the trench structure 402 into the first region 404 of the semiconductor substrate 406, with one or more source or emitter trenches 411 optionally interleaved between the power transistor gate trenches 410. Gate trenches 412 that form part of the cells of the current sense device 102 may laterally branch out from the trench structure 402 into the second region 408 of the semiconductor substrate 406, with one or more source or emitter trenches 413 optionally interleaved between the sense device gate trenches 412. The source or emitter trenches 413 of the current sense device 102 include a contact 414 for electrically connecting to the current sense contact pad CS. The gate trenches 410, 412 include gate electrodes electrically insulated from the semiconductor substrate 406 and electrically connected to the contact pad G of the semiconductor die. The gate contact pad G and the gate electrodes are out of view in FIGS. 8 and 9.

The device cells also include contacts 416 to an emitter region of a first conductivity type formed in a body region 418 of a second conductivity type opposite the first conductivity type. The emitter regions are out of view in FIGS. 8 and 9. The emitter regions of the power transistor cells collectively form the first load terminal Em of the power transistor Q_main, whereas the emitter regions of the sense cells collectively form the sense terminal Es of the current sense device 102. The power transistor Q_main has more cells and therefore a larger emitter area than the current sense device 102 (e.g., 10,000:1 power transistor to current sense emitter area ratio), such that the emitter area of the power transistor Q_main has more charge storage capacity for ESD energy than the emitter area of the current sense device 102.

For power MOSFET or JFET cells, the region of the first conductivity type formed in the body region 418 is instead a source region. A drift region 420 of the first conductivity type is disposed below the body region 418, and a collector region 422 (or a drain region for a power MOSFET or JFET) is disposed below the drift region 420. An optional region 423 of the first conductivity type may be implanted underneath the body region 418 as a type of barrier or carrier storage layer. The peak doping concentration of the optional barrier/carrier storage layer 423 is at least >10× that of the drift region 420. The optional barrier/carrier storage layer 423 may be used to increase carrier confinement in the drift region 420.

The first conductivity is n-type and the second conductivity type is p-type for n-channel devices, whereas the first conductivity is p-type and the second conductivity type is n-type for p-channel devices. The gate electrodes 414, emitter/source regions and body regions 418 of the power transistor cells are out of view in FIG. 8, since only a terminating part of the gate trenches 410 for the power transistor cells is illustrated.

In FIGS. 8 and 9, the resistive and/or diodic connection 106 include gaps 424 in the trench structure 402 through which the sense terminal Es of the current sense device 102 is electrically connected to the first load terminal Em of the power transistor Q_main. FIG. 9 illustrates the semiconductor substrate 406 in a region of one of the gaps 424 in the trench structure 402. As shown in FIG. 9, the body region 418 of the second conductivity type is disposed in the gaps 424 in the trench structure 402. A more heavily doped semiconductor material 426 of the second conductivity type (e.g., p+ for n-channel devices or n+ for p-channel devices) and/or a more heavily doped semiconductor material 428 of the first conductivity type (e.g., n+ for n-channel devices or p+ for p-channel devices) may also fill the gaps 424 in the trench structure 402, above the body region 418 of the second conductivity type.

If only semiconductor material of the second conductivity type fills the gaps 424 in the trench structure 402, then the resistive and/or diodic connection 106 is a resistive connection formed by the body region 418 of the second conductivity type. In one embodiment, the resistive connection formed by the part of the body region 418 of the second conductivity type that fills the gaps 424 in the trench structure 402 has an equivalent resistance of about 400 Ohms. The inventors observed that the resistive connection formed by the part of the body region 418 of the second conductivity type that fills the gaps 424 in the trench structure 402 has no negative impact on current sensor functionality regarding overload/short circuit detection, as compared to a reference design with no gaps in in the trench structure 402 between the first region 404 of the semiconductor substrate 406 that includes the power transistor Q_main and the second region 408 of the semiconductor substrate 406 that includes the current sense device 102.

If the heavily doped semiconductor material 426 of the second conductivity type and the heavily doped semiconductor material 428 of the first conductivity type also fill the gaps 424 in the trench structure 402, then the resistive and/or diodic connection 106 includes a resistive connection formed by the body region 418 of the second conductivity type in parallel with a diodic connection formed by the junction of the heavily doped semiconductor material 426 of the second conductivity type and the heavily doped semiconductor material 428 of the first conductivity type. The heavily doped semiconductor material 428 of the first conductivity type may be formed if the heavily p-doped semiconductor material 426 of the second conductivity type is present at the surface. In this case, the heavily doped n-type semiconductor material 428 of the first conductivity type is provided to avoid too low resistance between the current sense contact pad CS and the first load terminal contact pad. In one embodiment, the number and dimensions (e.g., length, width, depth, etc.) of the gaps 424 in the trench structure 102 are designed such that current leakage Ir between the sense terminal Es of the current sense device 102 and the first load terminal Em of the power transistor Q_main is at least ten times smaller than the current Is sensed by the current sense device 102 in an on-state of the power transistor Q_main.

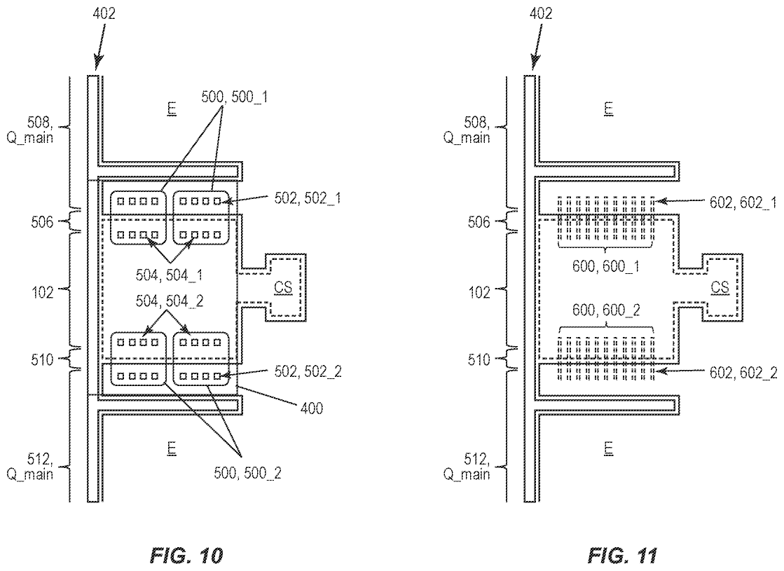

FIG. 10 illustrates a top plan view of the semiconductor die 100 in a region where the current sense device 102 borders the power transistor Q_main, according to another embodiment. In FIG. 10, the outline of the first load terminal contact pad E of the semiconductor die 100 is illustrated using a solid meandering line and the outline of the current sense contact pad CS is illustrated using a dashed meandering line, to provide an unobstructed view of the underlying components. Also in FIG. 10, the resistive and/or diodic connection 106 includes one or more doped polysilicon resistors 500 through which the sense terminal Es of the current sense device 102 is electrically connected to the first load terminal Em of the power transistor Q_main.

One or more first electrically conductive vias 502 may electrically connect each doped polysilicon resistor 500 to the first load terminal contact pad E of the semiconductor die 100. One or more second electrically conductive vias 504 may electrically connect each doped polysilicon resistor 500 to the current sense contact pad CS of the semiconductor die 100.

Each doped polysilicon resistor 500 may be separated from the front main surface of the semiconductor substrate 406 by an insulation layer 400 and each doped polysilicon resistor 500 may span the region of the semiconductor substrate 406 that separates the power transistor Q_main from the current sense device 102. For example, an interface or transition region of the semiconductor substrate 406 that separates the power transistor Q_main from the current sense device 102 may include the trench structure 402 shown in FIG. 8 but without the gaps 424. In this embodiment, each polysilicon resistor 500 is electrically connected to the sense terminal Es of the current sense device 102 by one or more third electrically conductive vias (out of view in FIG. 10) that extend through the insulation layer 400 formed above the semiconductor substrate 102 and to or into the emitter regions of the current sense device cells. Each polysilicon resistor 500 is electrically connected to the first load terminal Em of the power transistor Q_main by one or more fourth electrically conductive vias (also out of view in FIG. 10) that extend through the insulation layer 400 formed above the semiconductor substrate 102 and to or into the emitter regions of the power transistor device cells.

In FIG. 10, the resistive and/or diodic connection 106 includes one or more first doped polysilicon resistors 500_1 that span a first region 506 of the semiconductor substrate 406 that separates the current sense device 102 from a first part 508 of the power transistor Q_main and one or more second doped polysilicon resistors 500_2 that span a second region 510 of the semiconductor substrate 406 that separates the current sense device 102 from a second part 512 of the power transistor Q_main. Each first doped polysilicon resistor 500_1 is electrically connected to the first load terminal contact pad E of the semiconductor die 100 above the first part 508 of the power transistor Q_main by first electrically conductive vias 502_1 and to the current sense contact pad CS of the semiconductor die 100 above the current sense device 102 by second electrically conductive vias 504_1. Each second doped polysilicon resistor 500_2 is electrically connected to the first load terminal contact pad E of the semiconductor die 100 above the second part 512 of the power transistor Q_main by first electrically conductive vias 502_2 and to the current sense contact pad CS of the semiconductor die 100 above the current sense device 102 by second electrically conductive vias 504_2.

FIG. 11 illustrates a top plan view of the semiconductor die 100 in a region where the current sense device 102 borders the power transistor Q_main, according to another embodiment. In FIG. 11, the resistive and/or diodic connection 106 includes one or more doped polysilicon resistors 600 through which the sense terminal Es of the current sense device 102 is electrically connected to the first load terminal Em of the power transistor Q_main. Different than the embodiment shown in FIG. 10, the one or more doped polysilicon resistors 600 in FIG. 11 are disposed in trenches 602 formed in the front main surface of the semiconductor substrate 106. The trenches 602 laterally extend from the region 408 of the semiconductor substrate 406 that includes the current sense device 102 into the region 404 of the semiconductor substrate 406 that includes the power transistor Q_main.

Each doped polysilicon resistor 600 is electrically connected to the first load terminal contact pad E of the semiconductor die 100 at a first end of the trenches 602, e.g., by way of first electrically conductive vias (not shown in FIG. 11) that extend through the insulation layer 400 formed above the semiconductor substrate 102. Each doped polysilicon resistor 600 is electrically connected to the current sense contact pad CS of the semiconductor die 100 at a second end of the trenches 602 opposite the first end, e.g., by way of second electrically conductive vias (not shown in FIG. 11) that extend through the insulation layer 400 formed above the semiconductor substrate 102.

In FIG. 11, the resistive and/or diodic connection 106 includes a first doped polysilicon resistor 600_1 disposed in first trenches 602_1 formed in the front main surface of the semiconductor substrate 406 and laterally extending from a region of the semiconductor substrate 406 that includes the first part 508 of the power transistor Q_main into a region of the semiconductor substrate 406 that includes the current sense device 102. The resistive and/or diodic connection 106 further includes a second doped polysilicon resistor 600_2 disposed in second trenches 602_2 formed in the front main surface of the semiconductor substrate 406 and laterally extending from a region of the semiconductor substrate 406 that includes the second part 512 of the power transistor Q_main into the region of the semiconductor substrate 406 that includes the current sense device 102. The first doped polysilicon resistor 600_1 is electrically connected to the first load terminal contact pad E of the semiconductor die 100 above the first part 508 of the power transistor Q_main and to the current sense contact pad CS of the semiconductor die 100 above the current sense device 102. The second doped polysilicon resistor 600_2 is electrically connected to the first load terminal contact pad E of the semiconductor die 100 above the second part 512 of the power transistor Q_main and to the current sense contact pad CS of the semiconductor die 100 above the current sense device 102.

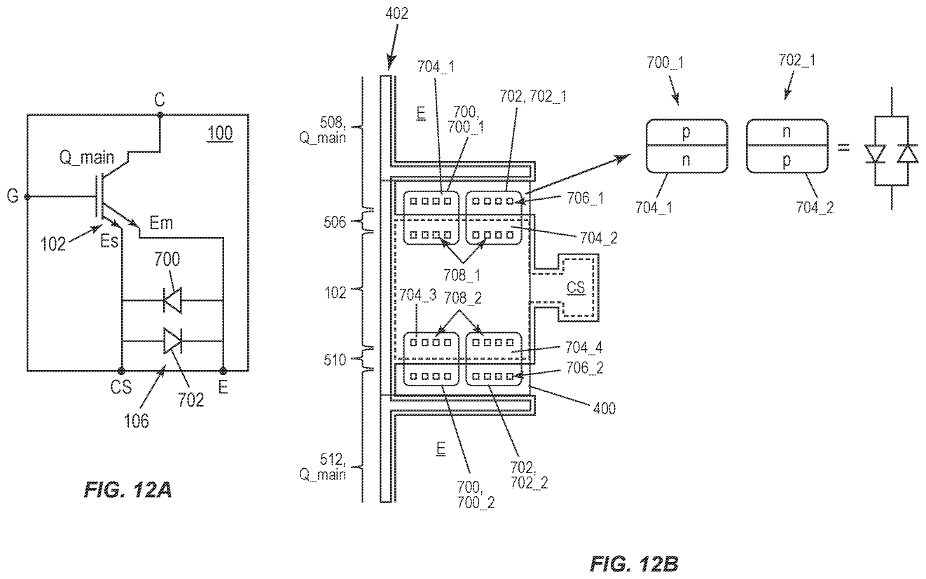

FIG. 12A illustrates a schematic diagram of the semiconductor die 100 and FIG. 12B illustrates a corresponding top plan view of the semiconductor die 100 in a region where the current sense device 102 borders the power transistor Q_main, according to another embodiment. In FIGS. 12A and 12B, the resistive and/or diodic connection 106 includes a first diode 700 electrically connected between the sense terminal Es of the current sense device 102 and the first load terminal Em of the power transistor Q_main and a second diode 702 antiparallel to the first diode 700. The diodes 700, 702 may be implemented as polysilicon diodes, e.g., as shown in FIG. 12B. During the off-state of the main power transistor Q_main, the diodes 700, 702 provide isolation between the current sense contact pad CS and the first load terminal contact pad E of the semiconductor die 100 up to at least +/−0.65V voltage imbalance. The isolation can be increased by using two or more diodes in series for each of the first diode 700 and the second diode 702 shown in FIG. 12A.

In FIG. 12B, the resistive and/or diodic connection 106 includes a first polysilicon pn diode 700_1 formed in a first polysilicon island 704_1 that is separated from the semiconductor substrate 406 by an insulation layer 400 and spans a first region 506 of the semiconductor substrate 406 that separates the current sense device 102 from a first part 508 of the power transistor Q_main. A second polysilicon pn diode 702_1 antiparallel to the first pn diode 700_1 is formed in a second polysilicon island 704_2 that is separated from the semiconductor substrate 406 by an insulation layer 400. The resistive and/or diodic connection 106 further includes another first polysilicon pn diode 700_2 formed in a third polysilicon island 704_3 that is separated from the semiconductor substrate 406 by an insulation layer 400 and spans a second region 510 of the semiconductor substrate 406 that separates the current sense device 102 from a second part 512 of the power transistor Q_main. A second polysilicon pn diode 702_2 antiparallel to the first pn diode 700_2 is formed in a fourth polysilicon island 704_4 that is separated from the semiconductor substrate 406 by an insulation layer 400.

The anode (or cathode) of the first polysilicon pn diode 700_1 and the cathode (or anode) of the antiparallel second polysilicon pn diode 702_1 that span the first region 506 of the semiconductor substrate 406 are both electrically connected to the first load terminal contact pad E of the semiconductor die 100 above the first part 508 of the power transistor Q_main by first electrically conductive vias 706_1. The cathode (or anode) of the first polysilicon pn diode 700_1 and the anode (or cathode) of the antiparallel second polysilicon pn diode 702_1 that span the first region 506 of the semiconductor substrate 406 are both electrically connected to the current sense contact pad CS of the semiconductor die 100 above the current sense device 102 by second electrically conductive vias 708_1.

The cathode (or anode) of the first polysilicon pn diode 700_2 and the anode (or cathode) of the antiparallel second polysilicon pn diode 702_2 that span the second region 510 of the semiconductor substrate 406 are both electrically connected to the first load terminal contact pad E of the semiconductor die 100 above the second part 512 of the power transistor Q_main by first electrically conductive vias 706_2. The anode (or cathode) of the first polysilicon pn diode 700_2 and the cathode (or anode) of the antiparallel second polysilicon pn diode 702_2 that span the second region 510 of the semiconductor substrate 406 are both electrically connected to the current sense contact pad CS of the semiconductor die 100 above the current sense device 102 by second electrically conductive vias 708_2.

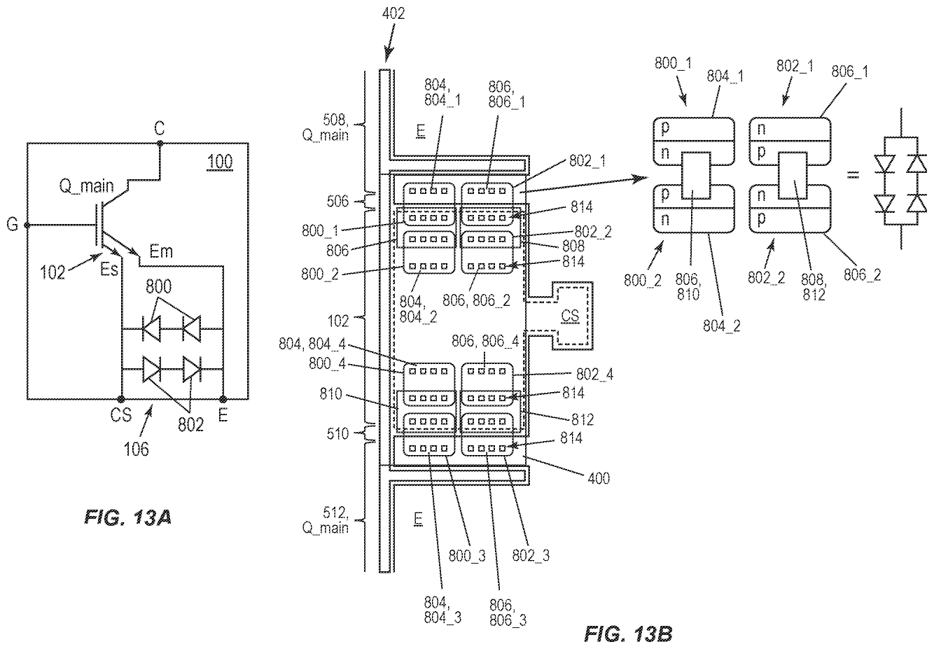

FIG. 13A illustrates a schematic diagram of the semiconductor die 100 and FIG. 13B illustrates a corresponding top plan view of the semiconductor die 100 in a region where the current sense device 102 borders the power transistor Q_main, according to another embodiment. In FIGS. 13A and 13B, the resistive and/or diodic connection 106 includes at least two series-connected first diodes 800 electrically connected between the sense terminal Es of the current sense device 102 and the first load terminal Em of the power transistor Q_main and at least two series-connected second diodes 802 are antiparallel to the at least two series-connected first diodes 800. During the off-state of the main power transistor Q_main, the series-connected diodes 800, 802 provide isolation between the current sense contact pad CS and the first load terminal contact pad E of the semiconductor die 100 up to at least +/−1.3V voltage imbalance. The isolation can be increased by using more than two diodes in series for each series-connected diode 800, 802 shown in FIG. 13A.

In FIG. 13B, the at least two series-connected first diodes 800 are formed in separate first polysilicon islands 804 that are separated from the semiconductor substrate 406 by an insulation layer 400 and electrically connected in series by a metallization structure 806 disposed above the first polysilicon islands 804. The at least two series-connected second diodes 802 are formed in separate second polysilicon islands 806 that are separated from the semiconductor substrate 406 by the insulation layer 400 and electrically connected in series by a metallization structure 808 disposed above the second polysilicon islands 806.

In FIG. 13B, a first one 800_1 of the at least two series-connected first diodes 800 formed in a first one 804_1 of the first polysilicon islands 804 and a first one 802_1 of the at least two series-connected second diodes 802 formed in a first one 806_1 of the second polysilicon islands 806 spans a first region 506 of the semiconductor substrate 406 that separates the current sense device 102 from a first part 508 of the power transistor Q_main. A second one 800_2 of the at least two series-connected first diodes 800 formed in a second one 804_2 of the first polysilicon islands 804 is in series with the first one 800_1 of the at least two series-connected first diodes 800 through a first metallization structure 806, and a second one 802_2 of the at least two series-connected second diodes 802 formed in a second one 806_2 of the second polysilicon islands 806 is in series with the first one 802_1 of the at least two series-connected second diodes 802 through a second metallization structure 808.

A third one 800_3 of the at least two series-connected first diodes 800 formed in a third one 804_3 of the first polysilicon islands 804 and a third one 802_3 of the at least two series-connected second diodes 802 formed in a third one 806_3 of the second polysilicon islands 806 spans a second region 510 of the semiconductor substrate 406 that separates the current sense device 102 from a second part 512 of the power transistor Q_main. A fourth one 800_4 of the at least two series-connected first diodes 800 formed in a fourth one 804_4 of the first polysilicon islands 804 is in series with the third one 800_3 of the at least two series-connected first diodes 800 through a third metallization structure 810, and a fourth one 802_4 of the at least two series-connected second diodes 802 formed in a fourth one 806_4 of the second polysilicon islands 806 is in series with the third one 802_3 of the at least two series-connected second diodes 802 through a fourth metallization structure 812. The electrical connections between the diodes 800, 802 and the overlying metal structures E, CS, 806, 808, 810, 812 are formed by respective electrically conductive vias 814. In FIG. 13B, only an outline of the first load terminal contact pad E of the semiconductor die 100, the current sense contact pad CS, and the metallization structures 806, 808, 810, 812 that interconnect the diodes 800, 802 are illustrated to provide an unobstructed view of the underlying components.

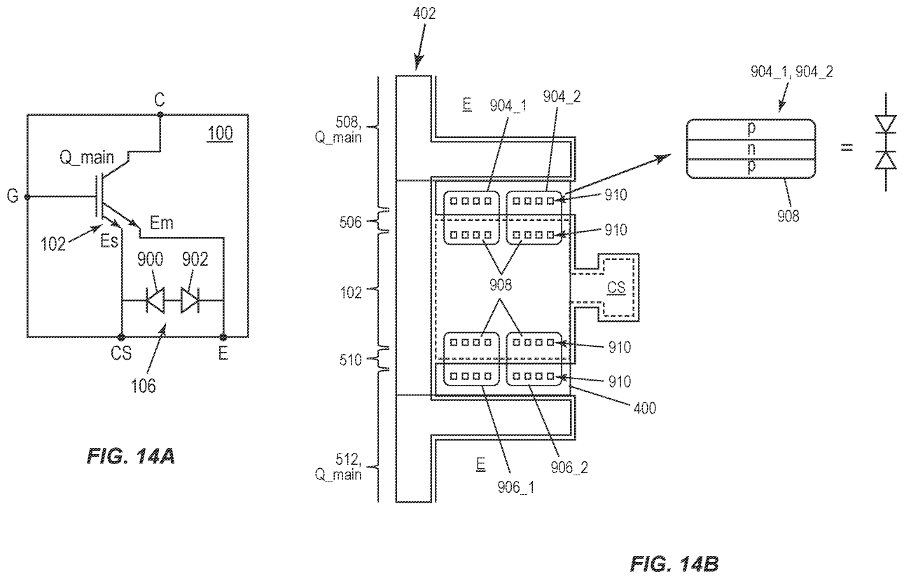

FIG. 14A illustrates a schematic diagram of the semiconductor die 100 and FIG. 14B illustrates a corresponding top plan view of the semiconductor die 100 in a region where the current sense device 102 borders the power transistor Q_main, according to another embodiment. In FIGS. 14A and 14B, the resistive and/or diodic connection 106 includes two or more diodes 900, 902 electrically connected in a Zener configuration between the sense terminal Es of the current sense device 102 and the first load terminal Em of the power transistor Q_main. The diodes 900, 902 may be implemented as polysilicon diodes, e.g., as shown in FIG. 14B. During the off-state of the main power transistor Q_main, the Zener-configured diodes 900, 902 provide isolation between the current sense contact pad CS and the first load terminal contact pad E of the semiconductor die 100 higher than +/−0.65V (e.g., for a single diode implementation at room temperature). The Zener isolation comes from the reverse breakdown. Accordingly, the isolation value is not bound to multiples of +/−0.65V (at room temperature) but instead the breakdown position can be designed at other voltages.

In FIG. 14B, the diodes 900, 902 electrically connected in a Zener configuration are implemented as two (2) first polysilicon pnp (or npn) diodes 904_1, 904_2 that span a first region 506 of the semiconductor substrate 406 that separates the current sense device 102 from a first part 508 of the power transistor Q_main. Two (2) second polysilicon pnp (or npn) diodes 906_1, 906_2 span a second region 510 of the semiconductor substrate 406 that separates the current sense device 102 from a second part 512 of the power transistor Q_main. Each pnp (or npn) diode is formed in respective polysilicon islands 908 that are separated from the semiconductor substrate 406 by an insulation layer 400. The electrical connections between the diodes 900, 902 and the overlying metal structures E, CS are formed by respective electrically conductive vias 910.

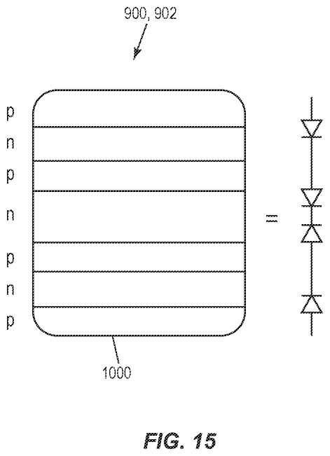

FIG. 15 illustrates a schematic diagram of one of the Zener-configured diodes 900, 902 shown in FIGS. 14B, according to another embodiment. In FIG. 15, each half of the Zener-configured diode 900, 902 includes two series-connected pn diodes where the innermost two pn diodes share a common cathode to enable the Zener configuration. The Zener-configured diode 900, 902 may be formed in a polysilicon island 1000 that is separated from the semiconductor substrate 406 by an insulation layer 400.

Although the present disclosure is not so limited, the following numbered examples demonstrate one or more aspects of the disclosure.

Example 1. A semiconductor die, comprising: a semiconductor substrate; a power transistor formed in the semiconductor substrate; a current sense device formed in the semiconductor substrate and occupying less area of the semiconductor substrate than the power transistor; a first contact pad electrically connected to a first load terminal of the power transistor; a second contact pad electrically connected to a sense terminal of the current sense device, wherein the second contact pad is dedicated to current sensing only; and a resistive and/or diodic connection between the sense terminal of the current sense device and the first load terminal of the power transistor, wherein the resistive and/or diodic connection is designed solely for ESD (electrostatic discharge) protection of the current sense device, by providing an ESD discharge path to the first load terminal of the power transistor.

Example 2. The semiconductor die of example 1, further comprising: a temperature sense device; and a third contact pad electrically connected to a terminal of the temperature sense device, wherein the current sense device is electrically and physically isolated from the temperature sense device, wherein the third contact pad is dedicated to temperature sensing only.

Example 3. The semiconductor die of example 1 or 2, wherein the resistive and/or diodic connection comprises a resistive connection having a resistance value such that current leakage between the sense terminal of the current sense device and the first load terminal of the power transistor is at least ten times smaller than a current sensed by the current sense device in an on-state of the power transistor.

Example 4. The semiconductor die of any of examples 1 through 3, wherein the resistive and/or diodic connection comprises a diodic connection that electrically isolates the terminals for voltage differences between the terminals that are below a threshold value and electrically shorts the terminals for voltage differences between the terminals that are above the threshold value.

Example 5. The semiconductor die of any of examples 1 through 4, wherein a trench structure laterally separates a first region of the semiconductor substrate that includes the power transistor from a second region of the semiconductor substrate that includes the current sense device, and wherein the resistive and/or diodic connection comprises a plurality of gaps in the trench structure through which the sense terminal of the current sense device is electrically connected to the first load terminal of the power transistor.

Example 6. The semiconductor die of example 5, wherein p-type semiconductor material and/or n-type semiconductor material fills the gaps in the trench structure.

Example 7. The semiconductor die of example 6, wherein the power transistor is an IGBT (insulated gate bipolar transistor), wherein the current sense device is an IGBT, wherein the first load terminal of the power transistor is an emitter terminal, wherein the sense terminal of the current sense device is an emitter terminal, and wherein the emitter terminal of the power transistor and the emitter terminal of the current sense device are electrically connected to one another by the p-type semiconductor material and/or the n-type semiconductor material that fills the gaps in the trench structure.

Example 8. The semiconductor die of any of examples 5 through 7, wherein the number and dimensions of the gaps in the trench structure are designed such that current leakage between the sense terminal of the current sense device and the first load terminal of the power transistor is at least ten times smaller than a current sensed by the current sense device in an on-state of the power transistor.

Example 9. The semiconductor die of any of examples 1 through 8, wherein the resistive and/or diodic connection comprises: one or more doped polysilicon resistors through which the sense terminal of the current sense device is electrically connected to the first load terminal of the power transistor.

Example 10. The semiconductor die of example 9, wherein one or more first electrically conductive vias electrically connect the one or more doped polysilicon resistors to the first contact pad, and wherein one or more second electrically conductive vias electrically connect the one or more doped polysilicon resistors to the second contact pad.

Example 11. The semiconductor die of example 9 or 10, wherein the one or more doped polysilicon resistors are separated from a first main surface of the semiconductor substrate by an insulation layer, and wherein each of the one or more doped polysilicon resistors spans a region of the semiconductor substrate that separates the power transistor from the current sense device.

Example 12. The semiconductor die of example 9, wherein the one or more doped polysilicon resistors are disposed in a plurality of trenches formed in a first main surface of the semiconductor substrate, wherein the plurality of trenches laterally extends from a first region of the semiconductor substrate that includes the current sense device into a second region of the semiconductor substrate that includes the power transistor, wherein the one or more doped polysilicon resistors are electrically connected to the first contact pad at a first end of the plurality of trenches, and wherein the one or more doped polysilicon resistors are electrically connected to the second contact pad at a second end of the plurality of trenches opposite the first end.

Example 13. The semiconductor die of any of examples 1 through 12, wherein the current sense device is laterally interposed between a first part of the power transistor and a second part of the power transistor such that the current sense device borders the first part of the power transistor on a first side of the current sense device and borders the second part of the power transistor on a second side of the current sense device different than the first side.

Example 14. The semiconductor die of example 13, wherein: the resistive and/or diodic connection comprises one or more first doped polysilicon resistors spanning a first region of the semiconductor substrate that separates the current sense device from the first part of the power transistor; the resistive and/or diodic connection further comprises one or more second doped polysilicon resistors spanning a second region of the semiconductor substrate that separates the current sense device from the second part of the power transistor; each of the one or more first doped polysilicon resistors is electrically connected to the first contact pad above the first part of the power transistor and to the second contact pad above the current sense device; and each of the one or more second doped polysilicon resistors is electrically connected to the first contact pad above the second part of the power transistor and to the second contact pad above the current sense device.

Example 15. The semiconductor die of example 13, wherein: the resistive and/or diodic connection comprises a first doped polysilicon resistor disposed in a plurality of first trenches formed in a first main surface of the semiconductor substrate and laterally extending from a region of the semiconductor substrate that includes the first part of the power transistor into a region of the semiconductor substrate that includes the current sense device; the resistive and/or diodic connection further comprises a second doped polysilicon resistor disposed in a plurality of second trenches formed in the first main surface of the semiconductor substrate and laterally extending from a region of the semiconductor substrate that includes the second part of the power transistor into the region of the semiconductor substrate that includes the current sense device; the first doped polysilicon resistor is electrically connected to the first contact pad above the first part of the power transistor and to the second contact pad above the current sense device; and the second doped polysilicon resistor is electrically connected to the first contact pad above the second part of the power transistor and to the second contact pad above the current sense device.

Example 16. The semiconductor die of any of examples 1 through 15, wherein the resistive and/or diodic connection comprises: one or more first diodes electrically connected between the sense terminal of the current sense device and the first load terminal of the power transistor; and one or more second diodes antiparallel to the one or more first diodes.

Example 17. The semiconductor die of example 16, wherein at least two series-connected first diodes are electrically connected between the sense terminal of the current sense device and the first load terminal of the power transistor, and wherein at least two series-connected second diodes are antiparallel to the at least two series-connected first diodes.

Example 18. The semiconductor die of example 17, wherein the at least two series-connected first diodes are formed in separate first polysilicon islands that are separated from the semiconductor substrate by an insulation layer, wherein the at least two series-connected first diodes are electrically connected in series by a metallization structure disposed above the first polysilicon islands, wherein the at least two series-connected second diodes are formed in separate second polysilicon islands that are separated from the semiconductor substrate by the insulation layer, and wherein the at least two series-connected second diodes are electrically connected in series by a metallization structure disposed above the second polysilicon islands.

Example 19. The semiconductor die of any of examples 1 through 18, wherein the resistive and/or diodic connection comprises: two or more diodes electrically connected in a Zener configuration between the sense terminal of the current sense device and the first load terminal of the power transistor.

Example 20. The semiconductor die of any of examples 1 through 19, wherein the resistive and/or diodic connection comprises a diodic connection in parallel with a resistive connection.

Example 21. A semiconductor die, comprising: a semiconductor substrate; an IGBT (insulated gate bipolar transistor) formed in the semiconductor substrate; a current sense device formed in the semiconductor substrate and occupying less area of the semiconductor substrate than the IGBT; an emitter contact pad electrically connected to an emitter terminal of the IGBT; a current sense contact pad electrically connected to an emitter terminal of the current sense device, wherein the current sense contact pad is dedicated to current sensing only; and a resistive and/or diodic connection between the emitter terminal of the current sense device and the emitter terminal of the IGBT, wherein the resistive and/or diodic connection is designed solely for ESD (electrostatic discharge) protection of the current sense device, by providing an ESD discharge path to the emitter terminal of the IGBT.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor die, comprising:
a semiconductor substrate;
a power transistor formed in the semiconductor substrate;
a current sense device formed in the semiconductor substrate and occupying less area of the semiconductor substrate than the power transistor;
a first contact pad electrically connected to a first load terminal of the power transistor;
a second contact pad electrically connected to a sense terminal of the current sense device, wherein the second contact pad is dedicated to current sensing only; and
a resistive and/or diodic connection between the sense terminal of the current sense device and the first load terminal of the power transistor,
wherein the resistive and/or diodic connection is designed solely for ESD (electrostatic discharge) protection of the current sense device, by providing an ESD discharge path to the first load terminal of the power transistor.

2. The semiconductor die of claim 1, further comprising:
a temperature sense device; and
a third contact pad electrically connected to a terminal of the temperature sense device,
wherein the current sense device is electrically and physically isolated from the temperature sense device,
wherein the third contact pad is dedicated to temperature sensing only.

3. The semiconductor die of claim 1, wherein the resistive and/or diodic connection comprises a resistive connection having a resistance value such that current leakage between the sense terminal of the current sense device and the first load terminal of the power transistor is at least ten times smaller than a current sensed by the current sense device in an on-state of the power transistor.

4. The semiconductor die of claim 1, wherein the resistive and/or diodic connection comprises a diodic connection that electrically isolates the terminals for voltage differences between the terminals that are below a threshold value and electrically shorts the terminals for voltage differences between the terminals that are above the threshold value.

5. The semiconductor die of claim 1, wherein a trench structure laterally separates a first region of the semiconductor substrate that includes the power transistor from a second region of the semiconductor substrate that includes the current sense device, and wherein the resistive and/or diodic connection comprises a plurality of gaps in the trench structure through which the sense terminal of the current sense device is electrically connected to the first load terminal of the power transistor.

6. The semiconductor die of claim 5, wherein p-type semiconductor material and/or n-type semiconductor material fills the gaps in the trench structure.

7. The semiconductor die of claim 6, wherein the power transistor is an IGBT (insulated gate bipolar transistor), wherein the current sense device is an IGBT, wherein the first load terminal of the power transistor is an emitter terminal, wherein the sense terminal of the current sense device is an emitter terminal, and wherein the emitter terminal of the power transistor and the emitter terminal of the current sense device are electrically connected to one another by the p-type semiconductor material and/or the n-type semiconductor material that fills the gaps in the trench structure.

8. The semiconductor die of claim 5, wherein the number and dimensions of the gaps in the trench structure are designed such that current leakage between the sense terminal of the current sense device and the first load terminal of the power transistor is at least ten times smaller than a current sensed by the current sense device in an on-state of the power transistor.

9. The semiconductor die of claim 1, wherein the resistive and/or diodic connection comprises:
one or more doped polysilicon resistors through which the sense terminal of the current sense device is electrically connected to the first load terminal of the power transistor.

10. The semiconductor die of claim 9, wherein one or more first electrically conductive vias electrically connect the one or more doped polysilicon resistors to the first contact pad, and wherein one or more second electrically conductive vias electrically connect the one or more doped polysilicon resistors to the second contact pad.

11. The semiconductor die of claim 9, wherein the one or more doped polysilicon resistors are separated from a first main surface of the semiconductor substrate by an insulation layer, and wherein each of the one or more doped polysilicon resistors spans a region of the semiconductor substrate that separates the power transistor from the current sense device.

12. The semiconductor die of claim 9, wherein the one or more doped polysilicon resistors are disposed in a plurality of trenches formed in a first main surface of the semiconductor substrate, wherein the plurality of trenches laterally extends from a first region of the semiconductor substrate that includes the current sense device into a second region of the semiconductor substrate that includes the power transistor, wherein the one or more doped polysilicon resistors are electrically connected to the first contact pad at a first end of the plurality of trenches, and wherein the one or more doped polysilicon resistors are electrically connected to the second contact pad at a second end of the plurality of trenches opposite the first end.

13. The semiconductor die of claim 1, wherein the current sense device is laterally interposed between a first part of the power transistor and a second part of the power transistor such that the current sense device borders the first part of the power transistor on a first side of the current sense device and borders the second part of the power transistor on a second side of the current sense device different than the first side.

14. The semiconductor die of claim 13, wherein:
the resistive and/or diodic connection comprises one or more first doped polysilicon resistors spanning a first region of the semiconductor substrate that separates the current sense device from the first part of the power transistor;
the resistive and/or diodic connection further comprises one or more second doped polysilicon resistors spanning a second region of the semiconductor substrate that separates the current sense device from the second part of the power transistor;
each of the one or more first doped polysilicon resistors is electrically connected to the first contact pad above the first part of the power transistor and to the second contact pad above the current sense device; and
each of the one or more second doped polysilicon resistors is electrically connected to the first contact pad above the second part of the power transistor and to the second contact pad above the current sense device.

15. The semiconductor die of claim 13, wherein:
the resistive and/or diodic connection comprises a first doped polysilicon resistor disposed in a plurality of first trenches formed in a first main surface of the semiconductor substrate and laterally extending from a region of the semiconductor substrate that includes the first part of the power transistor into a region of the semiconductor substrate that includes the current sense device;
the resistive and/or diodic connection further comprises a second doped polysilicon resistor disposed in a plurality of second trenches formed in the first main surface of the semiconductor substrate and laterally extending from a region of the semiconductor substrate that includes the second part of the power transistor into the region of the semiconductor substrate that includes the current sense device;
the first doped polysilicon resistor is electrically connected to the first contact pad above the first part of the power transistor and to the second contact pad above the current sense device; and
the second doped polysilicon resistor is electrically connected to the first contact pad above the second part of the power transistor and to the second contact pad above the current sense device.

16. The semiconductor die of claim 1, wherein the resistive and/or diodic connection comprises:
one or more first diodes electrically connected between the sense terminal of the current sense device and the first load terminal of the power transistor; and
one or more second diodes antiparallel to the one or more first diodes.

17. The semiconductor die of claim 16, wherein at least two series-connected first diodes are electrically connected between the sense terminal of the current sense device and the first load terminal of the power transistor, and wherein at least two series-connected second diodes are antiparallel to the at least two series-connected first diodes.

18. The semiconductor die of claim 17, wherein the at least two series-connected first diodes are formed in separate first polysilicon islands that are separated from the semiconductor substrate by an insulation layer, wherein the at least two series-connected first diodes are electrically connected in series by a metallization structure disposed above the first polysilicon islands, wherein the at least two series-connected second diodes are formed in separate second polysilicon islands that are separated from the semiconductor substrate by the insulation layer, and wherein the at least two series-connected second diodes are electrically connected in series by a metallization structure disposed above the second polysilicon islands.

19. The semiconductor die of claim 1, wherein the resistive and/or diodic connection comprises:
two or more diodes electrically connected in a Zener configuration between the sense terminal of the current sense device and the first load terminal of the power transistor.

20. The semiconductor die of claim 1, wherein the resistive and/or diodic connection comprises a diodic connection in parallel with a resistive connection.

21. A semiconductor die, comprising:
a semiconductor substrate;
an IGBT (insulated gate bipolar transistor) formed in the semiconductor substrate;
a current sense device formed in the semiconductor substrate and occupying less area of the semiconductor substrate than the IGBT;
an emitter contact pad electrically connected to an emitter terminal of the IGBT;
a current sense contact pad electrically connected to an emitter terminal of the current sense device, wherein the current sense contact pad is dedicated to current sensing only; and
a resistive and/or diodic connection between the emitter terminal of the current sense device and the emitter terminal of the IGBT,
wherein the resistive and/or diodic connection is designed solely for ESD (electrostatic discharge) protection of the current sense device, by providing an ESD discharge path to the emitter terminal of the IGBT.
